(19) United States
(12) Patent Application Publication
(10) Pub. No.: US 2025/0386535 A1
(43) Pub. Date: Dec. 18, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Hyun Seok Lee, Cheongju-si (KR); Su Jin Kim, Cheongju-si (KR); Tae Yeon Kim, Cheongju-si (KR); Gwang Hwi An, Cheongju-si (KR); Min Choi, Cheongju-si (KR)

(73) Assignees: Samsung Electronics Co., Ltd., Suwon-si (KR); Chungbuk National University Industry-Academic Cooperation Foundation, Cheongju (KR)

(21) Appl. No.: 18/990,103

(22) Filed: Dec. 20, 2024

(30) Foreign Application Priority Data
Jun. 12, 2024 (KR) 10-2024-0076612

(51) Int. Cl. H10D 30/43; H10D 30/01

(52) U.S. Cl. CPC H10D 30/43; H10D 30/014

(57) ABSTRACT

Provided is a semiconductor device with a three-dimensional gate structure that reduces a contact resistance between a metal and a semiconductor and a method of manufacturing the semiconductor. The semiconductor device includes a first nanowire extending in a first direction on a substrate, a junction barrier film surrounding the first nanowire at a first source/drain region and a second source/drain region at first and second ends of the first nanowire in the first direction, a gate electrode surrounding the first nanowire at a channel region in a middle portion of the first nanowire in the first direction with a gate insulating film positioned between the gate electrode and the first nanowire, and a contact electrode surrounding the junction barrier film.

### CROSS-REFERENCE TO RELATED APPLICATION

This U.S. non-provisional patent application is based on and claims priority under 35 U.S.C. § 119 to Korean Patent Application No. 10-2024-0076612, filed on Jun. 12, 2024, in the Korean Intellectual Property Office, the disclosure of which is hereby incorporated by reference herein in its entirety.

### BACKGROUND

The inventive concept relates to a semiconductor device, and more particularly, to a semiconductor device with a three-dimensional gate structure and a method of manufacturing the semiconductor device.

Recently, as silicon-based semiconductor devices, such as metal-oxide-semiconductor field-effect transistor (MOSFET), have been rapidly miniaturized, controlling the device leakage current due to a short channel effect has become very important. To this end, the latest MOSFET devices with a three-dimensional gate structure such as fin-FET or gate-all-around (GAA) have been miniaturized while efficiently controlling the leakage current. However, the reduction of the three-dimensional channel layer to a nanoscale size can rapidly increase the contact resistance between a metal and silicon. Therefore, efforts have continuously made to lower the contact resistance at the metal-silicon junction interface in the current complementary metal-oxide-semiconductor (CMOS) process.

### SUMMARY

The inventive concept provides a semiconductor device with a three-dimensional gate structure that reduces a contact resistance between a metal and a semiconductor and a method of manufacturing the semiconductor device.

In addition, the inventive concept is not limited to the above, and other inventive concepts can be clearly understood by those skilled in the art from the description below.

According to an aspect of the inventive concept, there is provided a semiconductor device including a first nanowire extending in a first direction on a substrate, in which the first nanowire has a first end, a middle portion and a second end in a first direction, a junction barrier film surrounding the first nanowire at a first source/drain region at the first end of the first nanowire and a second source/drain region at a second end, of the first nanowire in the first direction, a contact electrode surrounding the junction barrier film; and a gate electrode surrounding the first nanowire at a channel region in the middle portion of the first nanowire in the first direction with a gate insulating film positioned between the gate electrode and the first nanowire.

According to another aspect of the inventive concept, there is provided a semiconductor device including a first source/drain region and a second source/drain region spaced apart from each other in a first direction on a substrate, a junction barrier film at the first source/drain region and the second source/drain region, for example, in a tube shape, a channel region between the first source/drain region and the second source/drain region in the first direction, a gate electrode at the channel region with a gate insulating film positioned under the gate electrode, and a contact electrode over the junction barrier film.

According to another aspect of the inventive concept, there is provided a semiconductor device including a first source/drain region and a second source/drain region formed at a first and a second end of a nanowire extending in a first direction on a substrate, a channel region formed in a middle portion of the nanowire in the first direction, a junction barrier film surrounding the nanowire at the first source/drain region and the second source/drain region, for example, in a tube shape, a contact electrode surrounding the junction barrier film; and a gate electrode surrounding the nanowire at the channel region with a gate insulating film positioned between the gate electrode and the first nanowire, wherein the junction barrier film has a thickness of an atomic layer, which lowers the Schottky barrier between the semiconductor material (e.g., the first nanowire) and metal.

### BRIEF DESCRIPTION OF THE DRAWINGS

Embodiments will be more clearly understood from the following detailed description taken in conjunction with the accompanying drawings in which:

FIGS. 1A and 1B are perspective and cross-sectional views of a semiconductor device according to an embodiment;

FIGS. 2A to 2C are perspective views of a semiconductor device to illustrate a method of manufacturing the same according to an embodiment;

FIGS. 3A and 3B are perspective and cross-sectional views of a semiconductor device according to an embodiment;

FIGS. 4A to 4C are perspective views of a semiconductor device to illustrate a method of manufacturing the same according to an embodiment; and

FIGS. 5 to 8 are perspective views of semiconductor devices according to some embodiments.

### DETAILED DESCRIPTION OF THE EMBODIMENTS

Embodiments are described in detail with reference to the attached drawings. The same reference numerals are used for the same components in the drawings and duplicate descriptions thereof are omitted. The invention may be embodied in many different forms and should not be construed as limited to the example embodiments set forth herein. These example embodiments are just that—examples—and many implementations and variations are possible that do not require the details provided herein. The disclosure provides details of alternative examples, but such listing of alternatives is not exhaustive.

Items described in the singular herein may be provided in plural, as can be seen, for example, in the drawings. Thus, the description of a single item that is provided in plural should be understood to be applicable to the remaining plurality of items unless context indicates otherwise.

It will be understood that, although the terms first and second, may be used herein to describe various elements, components, and directions these elements, components, and directions should not be limited by these terms. Unless the context indicates otherwise, these terms are only used to distinguish one element, component, or direction from another one element, component, or direction for example as a naming convention.

As used herein, the terms “oxide” and “Ox” as used herein are intended to encompass oxides of multiple forms including oxides, dioxides, trioxides, etc.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

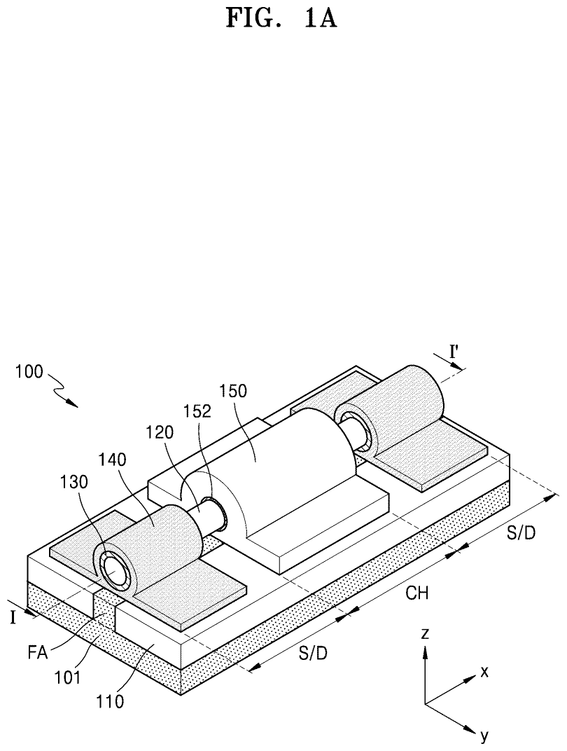

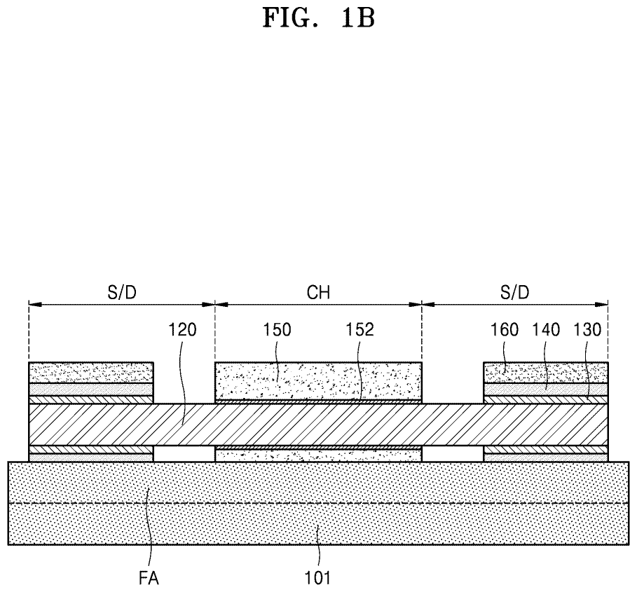

FIGS. 1A and 1B are perspective and cross-sectional views of a semiconductor device according to an embodiment, wherein FIG. 1B is a cross-sectional view taken along section I-I′ of FIG. 1A, FIG. 1B further adding a contact electrode 160 over the metal compound film 140.

Referring to FIGS. 1A and 1B, the semiconductor device 100 according to an embodiment may include a metal-oxide-semiconductor field-effect transistor (MOSFET) having a gate-all-around (GAA) structure. For example, the semiconductor device 100 according to an embodiment may include, for example, static random-access memory (SRAM) based on the MOSFET with the GAA structure, or various logic devices. However, the semiconductor device 100 according to an embodiment is not limited to the above.

Specifically, the semiconductor device 100 according to an embodiment may include a substrate 101, a device isolation film 110, a nanowire 120, a junction barrier film 130, a metal compound film 140, a gate electrode 150, and a contact electrode 160 (shown in FIG. 1B). As shown in FIG. 1A, the gate electrode 150 may surround an outer surface of the nanowire 120 with the gate insulating film 152 positioned between the nanowire 120 and the gate electrode 150.

The substrate 101 may be a semiconductor, such as silicon (Si) or germanium (Ge), or a compound semiconductor, such as SiGe, SiC, GaAs, InAs, or InP. In some embodiments, the substrate 101 may be formed of at least one of a group III-V material and a group IV material. The group III-V material may be a binary, ternary, or quaternary compound including at least one group III element and at least one group V element. The group III-V material may be a compound including at least one element of In, Ga, and Al as a group III element and at least one element of As, P, and Sb as a group V element. The group III-V material and the group IV material, such as Ge, may be used as channel material to create low-power, high-speed transistors. A high-performance complementary metal-oxide-semiconductor (CMOS) may be implemented by using a substrate formed of Group III-V material, e.g., GaAs, which has a higher electron mobility than a Si substrate, and a substrate formed of a semiconductor material, e.g., Ge, which has a higher hole mobility than the Si substrate.

In some embodiments, when forming an NMOS transistor on the substrate 101, the substrate 101 may be formed of any of the group III-V materials illustrated above. In some embodiments, when a PMOS transistor is formed on the substrate 101, at least a portion of the substrate 101 may be formed of Ge. In some embodiments, the substrate 101 may have a silicon-on-insulator (SOI) structure. The substrate 101 may include a conductive region, such as a well doped with impurities, or a structure doped with impurities.

The substrate 101 may be formed with the device isolation film 110 defining a fin FA. The device isolation film 110 may include an insulating liner that conformally covers the inner wall of the trench and a gap-fill insulating layer on the insulating liner. The insulating liner may be formed of an oxide film, SiN, SiON, SiBN, SiC, SiC:H, SiCN, SiCN:H, SiOCN, SiOCN:H, SiOC, SiO₂, polysilicon, or a combination thereof. In some embodiments, the gap-fill insulating layer may be formed of an oxide film. For example, the gap fill insulating layer may be formed of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or tonen silazene (TOSZ). However, the material of the gap-fill insulating layer is not limited to the above.

As shown in FIG. 1A, a top surface of the fin FA may be substantially at the same level or a similar level with a top surface of the device isolation film 110. In FIG. 1A, a structure in which one fin FA is disposed on the substrate 101, is shown for convenience, but in practice, a plurality of fins FA may be disposed on the substrate 101. Each of the plurality of fins FA may protrude from the substrate 101, may extend in an X direction, and may be spaced apart from each other in a Y direction. In some embodiments, the fin structure on the substrate 101 may be omitted.

According to example embodiments, one or more fins may protrude from a top surface of the substrate. It should be noted that in some embodiments, the active patterns AP may be part of the substrate, and in this manner, protruding from the substrate refers to protruding past a top main surface of the substrate (e.g., wherein the substrate itself has protrusions that extend beyond a main surface thereof). Reference to the substrate being “provided with” fin(s) may be used to generally indicate fin(s) as part of a substrate and/or fin(s) added to (e.g. grown from) a substrate.

The nanowire 120 may be arranged above the fin FA. For example, the nanowire 120 may be spaced apart from the top surface of the fin FA in the Z direction. However, in some embodiments, a portion of a bottom surface of the nanowire 120 may be in contact with the top surface of the fin FA. However, when a fin structure is not formed on the substrate 101, the nanowire 120 may be spaced apart from the top surface of the substrate 101 and placed above the substrate 101. However, in some embodiments, a portion of a bottom surface of the nanowire 120 may be in contact with the top surface of the substrate 101 or the device isolation film 110.

The nanowire 120 may have a columnar shape extending in the X direction. As shown in FIG. 1A, the nanowire 120 may have a cylindrical shape extending in the X direction. However, the shape of the nanowire 120 is not limited to the cylindrical shape. For example, the nanowire 120 may have an elliptical column or polygonal column shape extending in the X direction. The nanowire 120 may have a diameter or width of, e.g., about several nm (e.g., less than 10 nm) to about several tens of nm. However, the size of the nanowire 120 is not limited to the above. Alternative embodiments may include a nanosheet 170, which may have a rectangular cross sectional shape, as discussed further herein.

In some embodiments, the nanowire 120 may be formed from substantially the same material as the substrate 101. For example, the nanowire 120 may be formed of Si or SiGe. However, the material of nanowire 120 is not limited to the above.

The nanowire 120 may form source/drain regions S/D, for example at first and second ends of the nanowire in the X direction, and a channel region CH of the transistor, between the source/drain regions, in the X direction. For example, as shown in FIG. 1A, the nanowire 120 may include the source/drain regions S/D in both outer portions of the nanowire and the channel region CH in a central portion of the nanowire in the X direction. By adjusting a diameter or width of the nanowire 120, the channel width of the transistor and the corresponding channel current may be adjusted. When the diameter or width of the nanowire 120 is very thin of about several nm, a quantum confinement effect may appear and a threshold voltage Vt of the transistor may be adjusted by using the quantum confinement effect.

The junction barrier film 130 may surround the nanowire 120. Specifically, the junction barrier film 130 may surround the outer surface of the cylindrical nanowire 120 with a uniform thickness in the form of a circular tube. The junction barrier film 130 may have a thickness to prevent the occurrence of the Fermi-level pinning at metal-semiconductor junctions and lower the Schottky barrier. Accordingly, the junction barrier film 130 may have a very thin thickness equivalent to an atomic layer (e.g., the thickness of a single layer of atoms). For example, the junction barrier film 130 may have a thickness of about 0.7 nm to about 3 nm. However, the thickness of the junction barrier film 130 is not limited to the above.

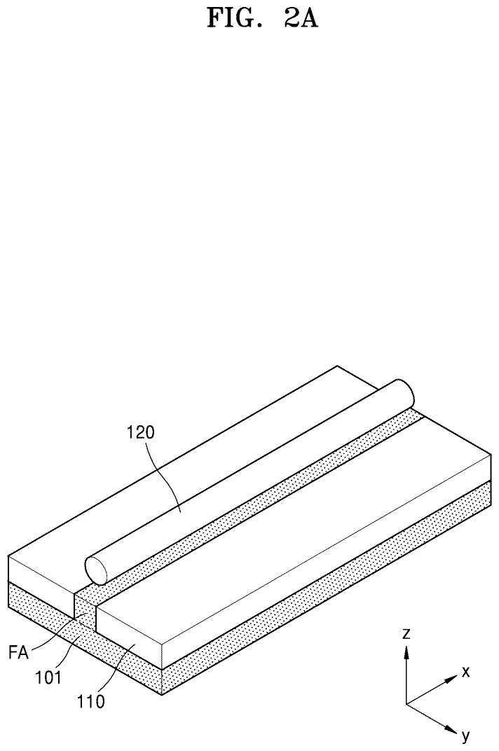

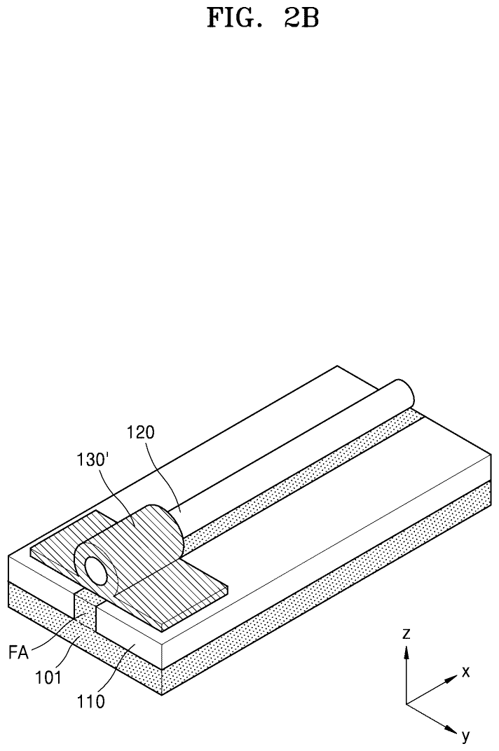

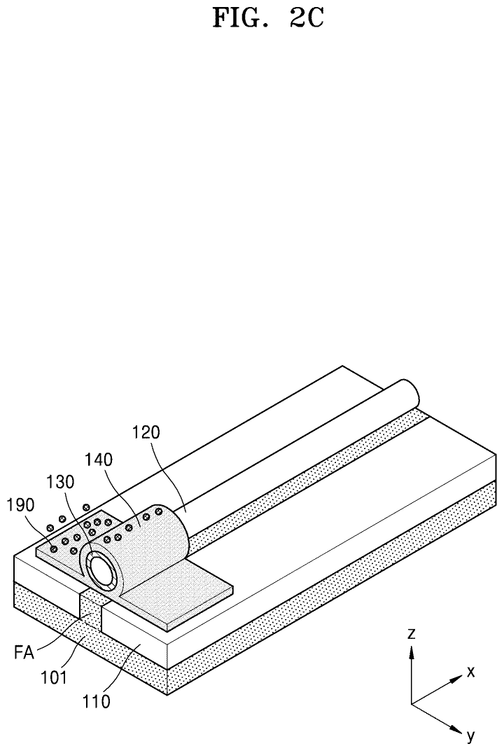

The junction barrier film 130 may include a film remaining after the metal oxide film undergoes a metallic phase transition. Accordingly, in some embodiments, the junction barrier film 130 may be referred to as a residual oxide layer (ROL). The metal oxide film may be any one of MoOx, TiOx, NiOx, or WOx. However, the material of the metal oxide film is not limited to the above. For example, the junction barrier film 130 may be formed of the film remaining after the metal oxide film undergoes a metallic phase transition through a nitridation or sulfurization process. The formation process of the junction barrier film 130 is described below in more detail with reference to FIGS. 2A to 2C.

The junction barrier film 130 may include, for example, at least one of a metal oxide, a metal oxynitride, a metal oxysulfide, or a silicon metal oxide. However, the material of the junction barrier film 130 is not limited to the above. The metal oxide of the junction barrier film 130 may be substantially the same as the material of the metal oxide film described above. For example, the metal oxide of the junction barrier film 130, which is a material included in the film remaining after the metal oxide film undergoes the metallic phase transition through the nitridation or sulfurization process, may be substantially the same as the material of the metal oxide film described above.

The metal oxynitride of the junction barrier film 130 may be formed when nitrogen permeates into or reacts with the remaining film after the metal oxide film undergoes the metallic phase transition through the nitridation process. For example, the metal oxynitride may be at least one of MoOxNy, TiOxNy, NiOxNy, or WOxNy. In addition, the metal oxysulfide of the junction barrier film 130 may be formed when sulfur permeates into or reacts with the remaining film after the metal oxide film undergoes the metallic phase transition through the sulfurization process. For example, the metal oxysulfide may be at least one of MoOxSy, TiOxSy, NiOxSy, or WOxSy. However, the silicon metal oxide of the junction barrier film 130 may be formed when Si of the nanowire 120 permeates into or reacts with the remaining film after the metal oxide film undergoes the metallic phase transition through the nitridation or sulfurization process.

The metal compound film 140 may surround the junction barrier film 130. Specifically, the metal compound film 140 may surround an outer surface of the junction barrier film 130 in the form of a circular tube. The metal compound film 140 may fill the space between the fin FA and the junction barrier film 130. In addition, the metal compound film 140 may extend from the junction barrier film 130 portion onto the top surface of the device isolation film 110 in the Y direction.

The metal compound film 140 may be formed through the metallic phase transition of the metal oxide film and may have conductivity. For example, the metal compound film 140 may be formed through the metallic phase transition due to the nitridation process on the metal oxide film. For example, the metal compound film 140 may be a conductive metal compound film, such as metal nitride. Specifically, when the metal oxide film be MoOx, TiOx, NiOx, or WOx, the metal compound film 140 may be a metal nitride, such as MoNx, TiNx, NiNx, or WNx. However, the metal compound film 140 is not limited to the metal nitride. For example, the metal compound film 140 may be formed through the metallic phase transition due to the sulfurization process of the metal oxide film. For example, the metal compound film 140 may be a conductive metal sulfide. The formation process of the metal compound film 140 is described below in more detail with reference to FIGS. 2A to 2C.

The gate electrode 150 may surround the nanowire 120 with the gate insulating film 152 positioned between the nanowire and the gate insulating film 152. Specifically, the gate electrode 150 may surround the outer surface of the cylindrical nanowire 120 in the form of a circular tube. Accordingly, the gate electrode 150 may have a GAA structure. In addition, the gate electrode 150 may extend from the nanowire 120 portion onto the top surface of the device isolation film 110 in the Y direction. However, although not shown, the gate insulating film 152 may also be disposed on a top surface of the fin FA and at least a part of the top surface of the device isolation film 110.

The gate insulating film 152 may be formed as a stacked structure of an interfacial layer and a high-k dielectric film. The interfacial layer may heal interfacial defects between the top surface of the fin FA and the high-k dielectric film and between the surface of the nanowire 120 and the high-k dielectric film. In some embodiments, the interfacial layer may be formed of a dielectric material film with a dielectric constant of about 9 or less, for example, a silicon oxide film, a silicon oxynitride film, or a combination thereof. In some embodiments, the interfacial layer may be formed of a silicate, a combination of a silicate and a silicon oxide film, or a combination of a silicon oxynitride film and a silicate. In some embodiments, the interfacial layer may be omitted.

The high-k dielectric film may be formed of a material having a dielectric constant greater than that of the silicon oxide film. For example, the high-k dielectric film may have a dielectric constant of about 10 to about 25. The high-k dielectric film may be formed of a hafnium (Hf)-based or zirconium (Zr)-based material. For example, the high-k dielectric film may be hafnium oxide (HfO₂), hafnium silicon oxide (HfSiO), hafnium silicon oxynitride (HfSiON), hafnium oxynitride (HfON), hafnium aluminum oxide (HfAlO), hafnium lanthanum oxide (HfLaO), zirconium oxide (ZrO₂), zirconium silicon oxide (ZrSiO), and the like.

In addition, the high-k dielectric film is not limited to the Hf-based or Zr-based material and may include other materials, such as lanthanum oxide (La₂O₃), lanthanum aluminum oxide (LaAlO₃), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc_{0.5}Ta_{0.5}O₃), red zinc niobate (PbZnNbO₃), and the like.

Such a high-k dielectric film may be formed through an atomic layer deposition (ALD), a chemical vapor deposition (CVD), or a physical vapor deposition (PVD). The high-k dielectric film may have a thickness of, for example, about 1 nm to about 4 nm. However, the thickness of the high-k dielectric film is not limited thereto.

The gate electrode 150 may be a metal-containing film for adjusting the work function and a metal-containing film for gap-filling that fills the upper space of the metal-containing film for adjusting the work function. In some embodiments, the gate electrode 150 may have a metal nitride film, a metal film, a conductive capping film, and a gap-fill metal film, stacked in this order. The metal nitride film and the metal film may each include at least one metal selected from Ti, W, Ru, Nb, Mo, Hf, Ni, Co, Pt, Yb, Tb, Dy, Er, or Pd. The metal nitride film and the metal film may each be formed through an ALD, a metal organic ALD (MOALD), a metal organic CVD (MOCVD), or the like.

The conductive capping film can function as a protective film that prevents oxidation of the surface of the metal film. In addition, the conductive capping film may function as a wetting layer to facilitate deposition when another conductive film is deposited on the metal film. The conductive capping film may be formed of a metal nitride, such as, but not limited to, TiN, TaN, or a combination thereof. The gap-fill metal film may extend over the conductive capping film. The gap-fill metal film may be formed of W. The gap-fill metal film may be formed by the ALD, CVD, or PVD process. The gap-fill metal film may fill a recessed space formed by the step between regions on the top surface of the conductive capping film without voids.

In some embodiments, the gate electrode 150 may be a stacked structure of TiAlC/TiN/W, a stacked structure of TiN/TaN/TiAlC/TiN/W, or a stacked structure of TiN/TaN/TiN/TiAlC/TiN/W. In the above-described stacked structures, the TiAlC film or the TiN film may function as a metal-containing film for adjusting the work function.

Although not shown in FIGS. 1A and 1B, a spacer may be formed on the gate electrode 150 and a cap layer may be formed on the top surface of the gate electrode 150. The spacer and the cap layer may form a gate structure together with the gate electrode 150. The spacer and the cap layer may be formed of, for example, a silicon nitride film.

The contact electrode 160 (see FIG. 1B) may surround the metal compound film 140. Specifically, the contact electrode 160 may surround an outer surface of the metal compound film 140 in the form of a circular tube. In addition, the contact electrode 160 may extend from the circular tube-shaped portion of the metal compound film 140 onto the top surface of the metal compound film 140 in the Y direction.

The contact electrode 160 may correspond to a contact electrode connected to the source/drain region S/D. The contact electrode 160 may be formed of a metal, a conductive metal nitride, or a combination thereof. For example, the contact electrode 160 may be formed of W, Cu, Al, Ti, Ta, Mo, Ru, TiN, TaN, MoN, alloys thereof, or combinations thereof. However, the material of the contact electrode 160 is not limited to the above. The junction barrier film 130, the metal compound film 140, and the contact electrode 160 may form the source/drain contact structure. In some embodiments, the metal compound film 140 may be treated as a part of the contact electrode 160.

The semiconductor device 100 according to an embodiment may include the nanowire 120 and the gate electrode 150 of a GAA structure. In addition, the semiconductor device 100 may include a source/drain contact structure including the junction barrier film 130, the metal compound film 140, and the contact electrode 160 on the source/drain region S/D. Therefore, the semiconductor device 100 according to an embodiment including the junction barrier film 130 between the nanowire and the contact electrode 160 or the metal compound film 140, at the source/drain region S/D, may prevent the Fermi-level pinning and lower the Schottky barrier in the metal-semiconductor junction structure, e.g., the metal-Si junction structure, thereby greatly reducing the contact resistance between metal and Si. In addition, because the semiconductor device 100 according to an embodiment does not consume the semiconductor material, e.g., Si, in the formation process of the junction barrier film 130, Si consumption in the source/drain regions S/D and/or the channel region CH may be minimized.

In the current CMOS process, efforts are continuously being made to lower contact resistance by forming metal silicide (mainly Ti, Co, and Ni-silicide) at the metal-Si junction interface. The metal silicide may cause ohmic contacts between metal-semiconductor junctions, thereby reducing the contact resistance. However, titanium-silicide (TiSi₂) and cobalt-silicide (CoSi₂) require complex processes and precise phase control through high-temperature heat treatment over 700 v, resulting in low process efficiency. In addition, nucleation growth in titanium-silicide and cobalt-silicide forms aggregation and voids at the junction interface and is therefore not suitable for very narrow contact areas. However, nickel-silicide (NiSi) may be most suitable for micro-processing due to its low formation temperature of 400° C. and formation mechanism by diffusion. However, a high temperature of 800° C. or higher or stress due to the device structure may cause local nuclear growth of NiSi2 and cause morphological issues at the junction interface. Furthermore, because all metal-silicide processes inevitably consume Si, Si in a rapidly reduced channel region may be overconsumed.

However, the semiconductor device 100 according to an embodiment including the very thin junction barrier film 130 of uniform thickness between the nanowire and the contact electrode 160, at the source/drain region, may solve problems caused by metal-silicide formation in the metal-Si junction structure. For example, the semiconductor device 100 according to an embodiment may reduce the contact resistance between metal and Si by preventing the occurrence of the Fermi-level pinning and lowering the Schottky barrier at the metal-Si junction through the junction barrier film 130. In addition, because the semiconductor device 100 according to an embodiment does not consume Si in the formation process of the junction barrier film 130, it is possible to solve the problem of overconsumption of Si in the channel region CH. Furthermore, the semiconductor device 100 according to an embodiment may tackle the reliability issues, caused by, e.g., aggregation, void formation, and phase instability in the metal-silicide process.

For example, the thin oxide film of the junction barrier film 130 may attenuate the wave function of electrons penetrating from the metal to Si at the metal-Si junction interface to prevent the Fermi-level pinning due to the metal induced gap states (MIGS) and lower the Schottky barrier, thereby reducing the contact resistance.

FIGS. 2A to 2C are perspective views of a semiconductor device to illustrate a method of manufacturing semiconductor devices according to an embodiment. The description may be made with reference to FIGS. 1A and 1B together and the details already described with reference to FIGS. 1A and 1B may be briefly described or omitted.

Referring to FIG. 2A, in methods of manufacturing the semiconductor device according to an embodiment, the fin FA and the nanowire 120 are first formed on the substrate 101. The fin FA may be defined on an upper portion of the substrate 101 by the device isolation film 110. The nanowire 120 may be disposed above the fin FA. For example, the nanowire 120 may be spaced apart from the top surface of the fin FA in the Z direction. The method of manufacturing the semiconductor device according to an embodiment may include a method of manufacturing the semiconductor device 100 in FIG. 1A.

In a method of forming the fin FA and the nanowire 120, a sacrificial layer and a semiconductor layer are formed on the substrate 101. The sacrificial layer may include, for example, SiGe, and the semiconductor layer may include, for example, Si. However, the materials of the sacrificial layer and the semiconductor layer are not limited to the above. For example, the sacrificial layer may not include the semiconductor material. Thereafter, the fin FA is formed on the substrate 101 through an etching process and patterns of the sacrificial layer and the semiconductor layer are formed on the fin FA. The fin FA, the sacrificial layer pattern, and the semiconductor layer pattern may have a shape extending in the X direction. Thereafter, by removing the sacrificial layer pattern through etching, the nanowire 120 due to the semiconductor layer pattern may be formed. In FIG. 2A, the entire nanowire 120 is shown as being spaced apart from the top surface of the fin FA. However, in practice, the nanowires may extend further in both directions in the X direction and may be supported by an unetched sacrificial layer pattern on both outer portions.

The method of forming the fin FA and the nanowire 120 is not limited to the above. For example, the fin FA and the nanowire 120 may be formed through various existing methods. In some embodiments, the fin FA may not be formed on the substrate 101. In some embodiments, a portion of the bottom surface of nanowire 120 may be in contact with the top surface of the fin FA or the substrate 101.

Referring to FIG. 2B, after forming the fin FA and the nanowire 120, a metal oxide film 130′ is uniformly formed on the fin FA, the nanowire 120 and the device isolation film 110 through the CVD or ALD process. The metal oxide film 130′ may include, e.g., any one of MoOx, TiOx, NiOx, SnOx, TaOx, NbOx, VOx, PdOx, or WOx. However, the material of the metal oxide film 130′ is not limited to the above. The metal oxide film 130′ may be formed to have a thickness of, for example, about several nanometers to about tens of nanometers. However, the thickness of the metal oxide film 130′ is not limited to the above.

The metal oxide film 130′ may be formed in both outer portions of the nanowire 120 corresponding to the source/drain region S/D. However, for convenience, in FIG. 2B, the metal oxide film 130′ is shown only in one outer portion of the nanowire 120. The metal oxide film 130′ may have a circular tube shape surrounding the outer surface of the nanowire 120 in the nanowire 120 portion. In addition, the metal oxide film 130′ may extend from the nanowire 120 portion onto the top surface of the device isolation film 110 in the Y direction. The space between the fin FA and the nanowire 120 may be filled with the metal oxide film 130′.

Referring to FIG. 2C, after forming the metal oxide film 130′, nitridation reaction gas 190, e.g., ammonia (NH₃) gas, is deposited on the metal oxide film 130′ by CVD. However, the nitridation reaction gas 190 is not limited to NH₃ gas. For example, the nitridation reaction gas 190 may include all kinds of precursor gas including nitrogen capable of nitriding the metal oxide film 130′. In addition, the nitridation reaction gas 190 may include any kind of precursor gas including hydrogen capable of reducing oxygen of the metal oxide film 130′.

Thereafter, a portion of the metal oxide film 130′ undergoes the metallic phase transition through the nitridation reaction using the nitridation reaction gas 190 to form the conductive metal compound film 140. Thus, the metal compound film 140 may include, for example, a conductive metal nitride. The metal nitride may include various materials depending on the material of the metal oxide film 130′. For example, the metal nitride may be MoNx, TiNx, NiNx, WNx, NbNx, TaNx, and the like. Specifically, for example, when the metal oxide film 130′ includes MoO₃ or MoO₂, NH₃ gas or N₂ and H₂ gas may be used as the nitridation reaction gas 190 to form the metal compound film 140 of MoN through the metallic phase transition due to the nitridation reaction.

In the process of forming the metal compound film 140, the entire metal oxide film 130′ may not undergo the metallic phase transition due to the nitridation reaction and a part of the metal oxide film 130′ may remain. The junction barrier film 130 may consist of the remaining part of the metal oxide film 130′. Thus, the junction barrier film 130 may include substantially the same material as the metal oxide film 130′. For example, the junction barrier film 130 may be any one of MoOx, TiOx, NiOx, SnOx, TaOx, NbOx, VOx, PdOx, or WOx.

In some embodiments, during the metallic phase transition due to the nitridation reaction, nitrogen may permeate into or react with the remaining film. In such a case, the junction barrier film 130 may be a metal oxynitride, such as MoOxNy, TiOxNy, NiOxNy, WOxNy, SnOxNy, TaOxNy, NbOxNy, and VOxNy. In addition, in some embodiments, during the metallic phase transition due to the nitridation reaction, Si of the nanowire 120 can permeate into or react with the remaining film. In such a case, the junction barrier film 130 may be a silicon metal oxide. Furthermore, during the metallic phase transition due to the nitridation reaction, nitrogen and Si permeate into or react with the remaining film so that the junction barrier film 130 may be a silicon metal oxynitride.

In the method of manufacturing the semiconductor device according to an embodiment, a three-dimensional metal compound film 140/junction barrier film 130/nanowire 120 junction structure may be formed through the metallic phase transition due to the nitridation reaction. Specifically, for example, when the metal oxide film is MoO₃, a three-dimensional MoN/MoO₃/Si junction structure may be formed. Thereafter, the contact electrode 160 may be formed on the metal compound film 140. The contact electrode 160 may surround the metal compound film 140 in the nanowire 120 portion and may extend from the nanowire 120 portion in the Y direction to cover the top surface of the metal compound film 140.

The gate electrode 150 may be formed before the formation of the source/drain contact structure with the junction barrier film 130, the metal compound film 140, and the contact electrode 160. However, in some embodiments, the gate electrode 150 may be formed after the formation of the source/drain contact structure.

Although the method of forming the junction barrier film 130 and the metal compound film 140 through the metallic phase transition due to the nitridation reaction on the metal oxide film 130′ has been described, the method of forming the junction barrier film 130 and the metal compound film 140 is not limited thereto. For example, the junction barrier film 130 and the metal compound film 140 may be formed through the metallic phase transition due to the sulfurization reaction on the metal oxide film 130′.

Accordingly, the metal compound film 140 may be, for example, conductive metal sulfide. The metal sulfide may be various materials depending on the material of the metal oxide film 130′. Specifically, for example, when the metal oxide film 130′ includes MoO₃ or MoO₂, H₂S gas may be used as a sulfurization reaction gas to form the metal compound film 140 of MoS₂ through the metallic phase transition due to the sulfurization reaction. The sulfurization reaction gas is not limited to the H₂S gas. For example, the sulfurization reaction gas may include all kinds of precursor gas including sulfur capable of sulfurizing the metal oxide film 130′.

In addition, in the process of forming the metal compound film 140, the entire metal oxide film 130′ does not undergo the metallic phase transition due to the sulfurization reaction and a part of the metal oxide film 130′ may remain. The junction barrier film 130 may consist of the remaining part of the metal oxide film 130′. Thus, the junction barrier film 130 may be substantially the same material as the metal oxide film 130′. For example, the junction barrier film 130 may be any one of MoOx, TiOx, NiOx, or WOx.

In some embodiments, during the metallic phase transition due to the sulfurization reaction, sulfur may permeate into or react with the remaining film. In such a case, the junction barrier film 130 may be a metal oxysulfide, such as MoOxSy, TiOxSy, NiOxSy, and WOxSy. In addition, in some embodiments, during the metallic phase transition due to the sulfurization reaction, Si of the nanowire 120 may permeate into or react with the remaining film. In such a case, the junction barrier film 130 may be a silicon metal oxide. Furthermore, during the metallic phase transition due to the sulfurization reaction, sulfur and Si permeate into or react with the remaining film so that the junction barrier film 130 may be a silicon metal oxide sulfide.

In the method of manufacturing the semiconductor device according to an embodiment, a three-dimensional metal compound film 140/junction barrier film 130/nanowire 120 junction structure may be formed through the metallic phase transition due to the sulfurization reaction. Specifically, for example, when the metal oxide film 130′ be MoO₃, a three-dimensional MoS₂/MoO₃/Si junction structure may be formed. Thereafter, the contact electrode 160 may be formed on the metal compound film 140. The contact electrode 160 may surround the metal compound film 140 in the nanowire 120 portion and may extend from the nanowire 120 portion in the Y direction to cover the top surface of the metal compound film 140.

In the method of manufacturing the semiconductor device according to an embodiment, the metallic phase transition due to the nitridation or sulfurization reaction may be precisely controlled to form the junction barrier film 130 having a thickness of an atomic layer at the semiconductor junction interface, e.g., Si junction interface. For example, the junction barrier film 130 may be formed to surround the nanowire 120 with a uniform thickness of about 0.7 nm to about 3 nm. The metal phase transition due to the nitridation or sulfurization reaction may be controlled through the amount of nitridation reaction gas 190 or sulfurization reaction gas, the process time, the process temperature, and the like. In addition, in some embodiments, a plasma process may be added to control the metallic phase transition due to the nitridation or sulfurization reaction.

In the method of manufacturing a semiconductor device according to an embodiment, by forming the very thin junction barrier film 130 of the metal oxide on the semiconductor interface, the Fermi-level pinning may be suppressed and the Schottky barrier may be lowered to reduce the contact resistance between the metal and the semiconductor. In addition, in the method of manufacturing the semiconductor device according to an embodiment, the three-dimensional metal-semiconductor junction structure may be formed without consuming Si.

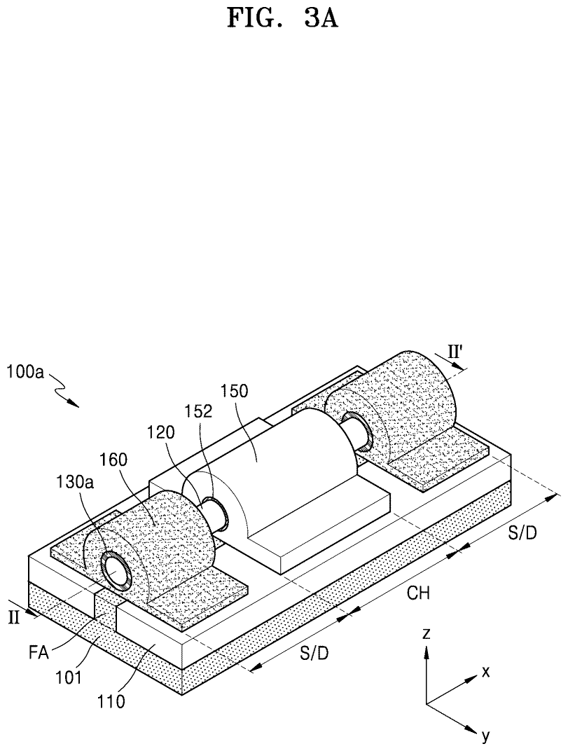

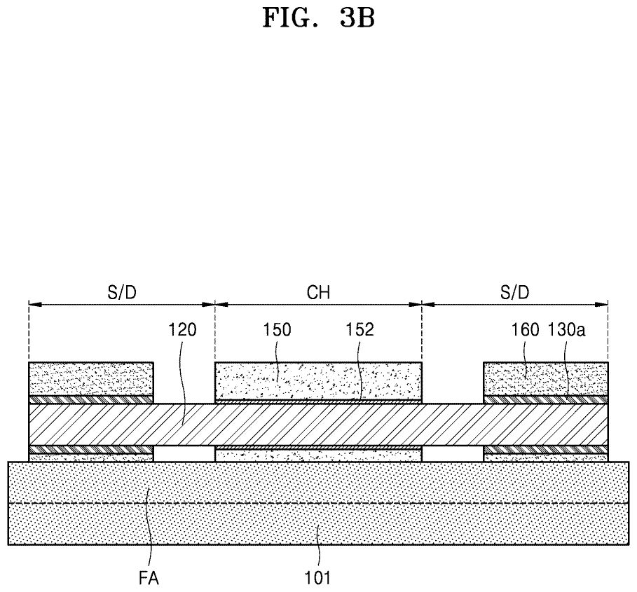

FIGS. 3A and 3B are perspective and cross-sectional views of a semiconductor device according to an embodiment, in which FIG. 3B is a cross-sectional view taken along section II-II′ of FIG. 3A. Details already described with reference to FIGS. 1A to 2C may be briefly described or omitted.

Referring to FIGS. 3A and 3B, the semiconductor device 100a according to an embodiment is similar to the semiconductor device 100 of FIG. 1A but may be different from the semiconductor device 100 in FIG. 1A in the source/drain contact structure. Specifically, the semiconductor device 100a according to an embodiment may include a substrate 101, a device isolation film 110, a nanowire 120, a junction barrier film 130a, a gate electrode 150, and a contact electrode 160. The gate electrode 150 may surround an outer surface of the nanowire 120 with the gate insulating film 152 positioned between the gate electrode 150 and the nanowire 120. The substrate 101, the device isolation film 110, the nanowire 120, the gate electrode 150, the gate insulating film 152 and the contact electrode 160 are the same as those described in the semiconductor device 100 of FIG. 1A.

However, in the semiconductor device 100a according to an embodiment, the metal compound film is not formed. Thus, the contact electrode 160 may be formed directly on the junction barrier film 130a. Accordingly, the contact electrode 160 may surround the outer surface of the junction barrier film 130a in the form of a circular tube. In addition, the contact electrode 160 may extend from the junction barrier film 130a portion onto the top surface of the device isolation film 110 in the Y direction.

The junction barrier film 130a may surround the nanowire 120. Specifically, the junction barrier film 130a may surround the outer surface of the cylindrical nanowire 120 with a uniform thickness in the form of a circular tube. The junction barrier film 130a may have a thickness to prevent the occurrence of the Fermi-level pinning and lower the Schottky barrier at the metal-semiconductor junction. Accordingly, the junction barrier film 130a may have a very thin thickness of an atomic layer. For example, the junction barrier film 130a may have a thickness of about 0.7 nm to about 3 nm. However, the thickness of the junction barrier film 130a is not limited to the above.

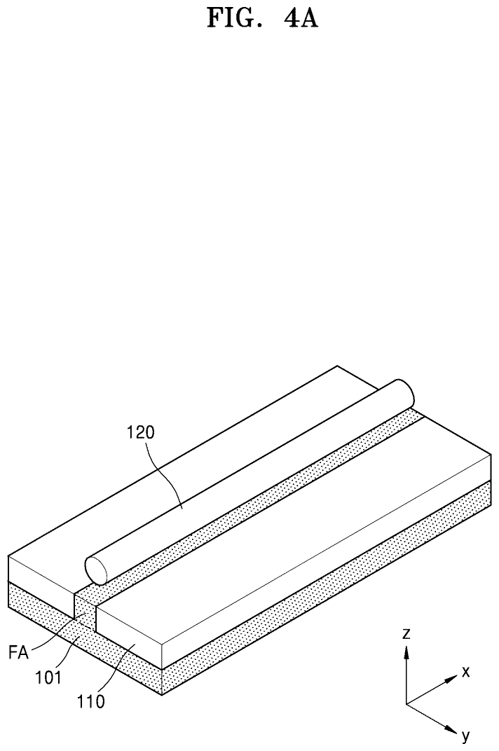

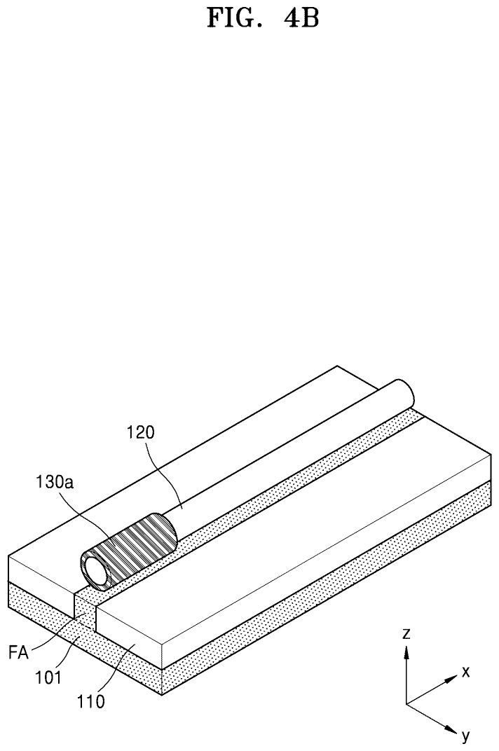

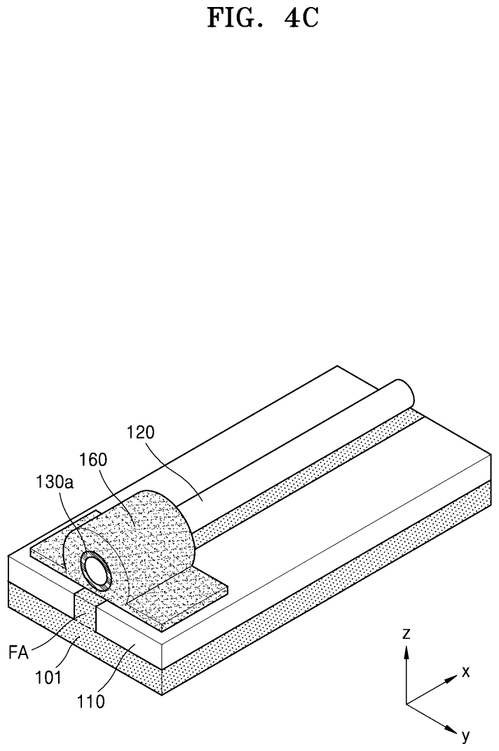

The junction barrier film 130a may include a transition metal dichalcogenide (TMD) material or a two-dimensional material. The TMD material may be one or more of MoS₂, MoSe₂, MoTe₂, WS₂, WSe₂, WTe₂, NbS₂, NbSe₂, NbTe₂, TaS₂, TaSe₂, TaTe₂, PdS₂, PdSe₂, PdTe₂, VS₂, VSe₂, or VTe₂. However, the TMD material is not limited to the above. In some embodiments, the junction barrier film 130a may be metal sulfide. In addition, the junction barrier film 130a may be a metal oxide or a metal oxysulfide due to oxidation of the metal sulfide. The junction barrier film 130a may be formed to uniformly cover the outer surface of the nanowire 120 through ALD. The formation process of the junction barrier film 130a is described below in more detail with reference to FIGS. 4A to 4C.

The semiconductor device 100a according to an embodiment may include the nanowire 120 and the gate electrode 150 of a GAA structure. In addition, the semiconductor device 100a may include a source/drain contact structure with the junction barrier film 130a and the contact electrode 160 on the nanowire 120 in the source/drain region S/D. The semiconductor device 100a according to an embodiment, including the junction barrier film 130a between the nanowire 120 and the contact electrode 160 in the source/drain region S/D of the nanowire, may prevent the Fermi-level pinning and lower the Schottky barrier in the metal-semiconductor junction structure, e.g., the metal-Si junction structure, thereby greatly reducing the contact resistance between metal and Si. In addition, because the semiconductor device 100a according to an embodiment does not consume the semiconductor material, e.g., Si, in the formation process of the junction barrier film 130a, the consumption of Si in the source/drain region S/D and/or the channel region CH may be minimized. Furthermore, the semiconductor device 100a according to an embodiment may tackle the reliability issues caused by aggregation, void formation, and phase instability in the metal-silicide process.

FIGS. 4A to 4C are perspective views of a semiconductor device to illustrate a method of manufacturing the same according to an embodiment. The description may be made with reference to FIGS. 3A and 3B together and the details already described with reference to FIGS. 1A to 3B may be briefly described or omitted.

Referring to FIG. 4A, in the method of manufacturing the semiconductor device according to an embodiment, the fin FA and the nanowire 120 are first formed on the substrate 101. The fin FA may be defined in an upper portion of the substrate 101 by the device isolation film 110. The nanowire 120 may be disposed above the fin FA. For example, the nanowire 120 may be spaced apart from the top surface of the fin FA in the Z direction. The method of manufacturing the semiconductor device according to an embodiment may include, for example, a method of manufacturing the semiconductor device 100a of FIG. 3A.

A method of forming the fin FA and the nanowire 120 is the same as that described with reference to FIG. 2A. However, the method of forming the fin FA and the nanowire 120 is not limited to that described with reference to FIG. 2A. For example, the fin FA and the nanowire 120 may be formed through various existing published methods. In addition, in some embodiments, the fin FA may not be formed on the substrate 101. In some embodiments, a portion of the bottom surface of nanowire 120 may be in contact with the top surface of the fin FA or the substrate 101.

Referring to FIG. 4B, after forming the fin FA and the nanowire 120, the junction barrier film 130a is uniformly formed on the nanowire 120 through the ALD process. The junction barrier film 130a may be metal sulfide, such as MoS2. In addition, the junction barrier film 130a may be a TMD material or a two-dimensional material with a broader concept than metal sulfide. The TMD material may be one or more of MoS₂, MoSe₂, MoTe₂, WS₂, WSe₂, WTe₂, NbS₂, NbSe₂, NbTe₂, TaS₂, TaSe₂, TaTe₂, PdS₂, PdSe₂, PdTe₂, VS₂, VSe₂, or VTe₂.

The junction barrier film 130a may be formed to a very thin thickness of an atomic layer through the ALD process. For example, the junction barrier film 130a may be formed to a thickness of about 0.7 nm to about 3 nm. However, the thickness of the junction barrier film 130a is not limited to the above. In addition, the process of forming the junction barrier film 130a is not limited to the ALD process. For example, the junction barrier film 130a may be formed by precisely performing the CVD process.

The junction barrier film 130a may be formed in both outer portions of the nanowire 120 corresponding to the source/drain region S/D. However, for convenience, in FIG. 4B, the junction barrier film 130a is shown only in one outer portion of the nanowire 120. The junction barrier film 130a may have a circular tube shape surrounding the outer surface of the cylindrical nanowire 120.

Referring to FIG. 4C, after forming the junction barrier film 130a, the contact electrode 160 is formed on the junction barrier film 130a. The contact electrode 160 may surround the outer surface of the junction barrier film 130a in the form of a circular tube. In addition, the contact electrode 160 may extend from the junction barrier film 130a portion onto the top surface of the device isolation film 110 in the Y direction.

In the method of manufacturing a semiconductor device according to an embodiment, a three-dimensional contact electrode 160/junction barrier film 130a/nanowire 120 junction structure may be formed. Specifically, for example, when the junction barrier film 130a is metal sulfide of MoS2, a three-dimensional metal/MoS₂/Si junction structure may be formed. In addition, when the junction barrier film 130a is the TMD material, the three-dimensional metal/TMD/Si junction structure may be formed.

In the method of manufacturing the semiconductor device according to an embodiment, by forming the very thin junction barrier film 130a of the metal sulfide or the TMD material on the semiconductor interface, the Fermi-level pinning may be suppressed and the Schottky barrier may be lowered to reduce the contact resistance between the metal and the semiconductor. In addition, in the method of manufacturing the semiconductor device according to an embodiment, the three-dimensional metal-semiconductor junction structure may be formed without consuming Si.

In some embodiments, an additional oxidation reaction may be performed on the junction barrier film 130a before forming the contact electrode 160 on the junction barriers film 130a. Through this further oxidation reaction to the junction barrier film 130a, the junction barrier film 130a may include the metal oxide, the metal sulfide or the TMD material containing oxygen. For a specific example, when the junction barrier film 130a initially includes metal sulfide of MoS2, the material included in the junction barrier film 130a may be changed to MoOx or MoOxSy through the additional oxidation reaction.

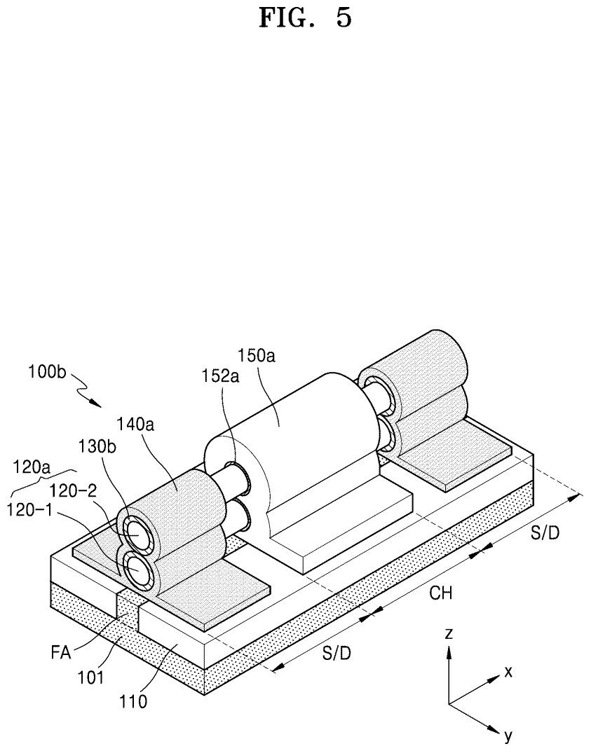

FIGS. 5 to 8 are perspective views of semiconductor devices according to some embodiments. Details already described with reference to FIGS. 1A to 4C may be briefly described or omitted.

Referring to FIG. 5, a semiconductor device 100b according to an embodiment may be different from the semiconductor device 100 of FIG. 1A in the structure of nanowire 120a. Specifically, the semiconductor device 100b according to an embodiment may include a substrate 101, a device isolation film 110, a nanowire 120a, a junction barrier film 130b, a metal compound film 140a, a gate electrode 150a, a gate insulating film 152a, and a contact electrode. The substrate 101, the device isolation film 110, the junction barrier film 130b, the metal compound film 140a, the gate electrode 150a, the gate insulating film 152a, and the contact electrode are the same as those described in the semiconductor device 100 of FIG. 1A. However, as the nanowire 120a includes two individual nanowires, a first nanowire 120-1 and a second nanowire 120-2, the junction barrier film 130b, the metal compound film 140a, the gate insulating film 152a, and the gate electrode 150a may be modified to surround the two individual nanowires 120-1 and 120-2.

The nanowire 120a may include two separate nanowires 120-1 and 120-2, i.e., a first nanowire 120-1 and a second nanowire 120-2. The first nanowire 120-1 may be spaced apart from a top surface of the fin FA and positioned above the fin FA. In addition, the second nanowire 120-2 may be spaced apart from the first nanowire 120-1 and positioned above the first nanowire 120-1.

Such a structure of the nanowire 120a may be formed by alternately stacking a sacrificial layer and the semiconductor layer into four layers on the substrate 101 in the method of forming the fin FA and the nanowire 120 of FIG. 2A, followed by a subsequent process. In addition, the junction barrier film 130b and the metal compound film 140a may be formed on the nanowire 120a through the processes of FIGS. 2A to 2C.

In the semiconductor device 100b according to an embodiment, the nanowire 120a includes two individual nanowires, first nanowire 120-1 and second nanowire 120-2, but the number of the individual nanowires included in the nanowire 120a is not limited to two. For example, the nanowire 120a may include three or more individual nanowires. In addition, the semiconductor device 100b according to an embodiment has a structure in which the junction barrier film 130b and the metal compound film 140a are formed on the nanowire 120a and the contact electrode is formed on the metal compound film 140a. However, the structure of the semiconductor device 100b is not limited thereto. For example, the semiconductor device 100b may have a structure in which only the junction barrier film 130b is formed on the nanowire 120a and the contact electrode is formed on the junction barrier film 130b.

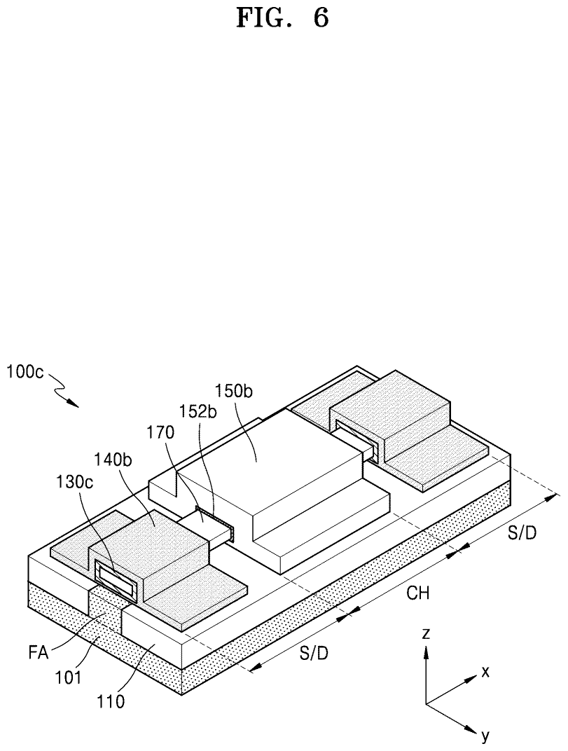

Referring to FIG. 6, a semiconductor device 100c according to an embodiment may differ from the semiconductor device 100 of FIG. 1A in that the semiconductor device 100c includes a nanosheet 170 instead of a nanowire. Specifically, the semiconductor device 100b according to an embodiment may include a substrate 101, a device isolation film 110, a nanosheet 170, a junction barrier film 130c, a metal compound film 140b, the gate insulating film 152b, a gate electrode 150b, and a contact electrode. The substrate 101, the device isolation film 110, the junction barrier film 130c, the metal compound film 140b, the gate insulating film 152b, the gate electrode 150b, and the contact electrode are the same as those described in the semiconductor device 100 of FIG. 1A. As the nanosheet 170 is of a different shape from the nanowire, the junction barrier film 130c, the metal compound film 140b, the gate insulating film 152b, and the gate electrode 150b may be transformed into a shape surrounding the nanosheet 170. As a non-limiting example, a nanosheet 170 may have a rectangular cross-sectional shape.

The nanosheet 170 may be spaced apart from the top surface of the fin FA and positioned above the fin FA. The nanosheet 170 may have a sheet structure. For example, the nanosheet 170 may have a sheet structure with a thickness of several nm in the Z direction and a width of about several nm to about tens of nm in the X direction and the Y direction. The size of the nanosheet 170 is not limited to the above. In the semiconductor device 100c according to an embodiment, the gate electrode 150b may have a GAA structure surrounding the four outer surfaces of the nanosheet 170. Accordingly, the semiconductor device 100c according to an embodiment may include a MOSFET having the GAA structure.

In the semiconductor device 100c according to an embodiment, one nanosheet 170 is arranged but the number of nanosheets 170 is not limited to one. For example, two or more nanosheets 170 spaced apart from each other may be arranged in a stacked structure. In addition, the semiconductor device 100c according to an embodiment has a structure in which the junction barrier film 130c and the metal compound film 140b are formed on the nanosheet 170 and the contact electrode is formed on the metal compound film 140b. However, the structure of the semiconductor device 100c is not limited thereto. For example, the semiconductor device 100c may have a structure in which only the junction barrier film 130c is formed on the nanosheet 170 and the contact electrode is formed on the junction barrier film 130c.

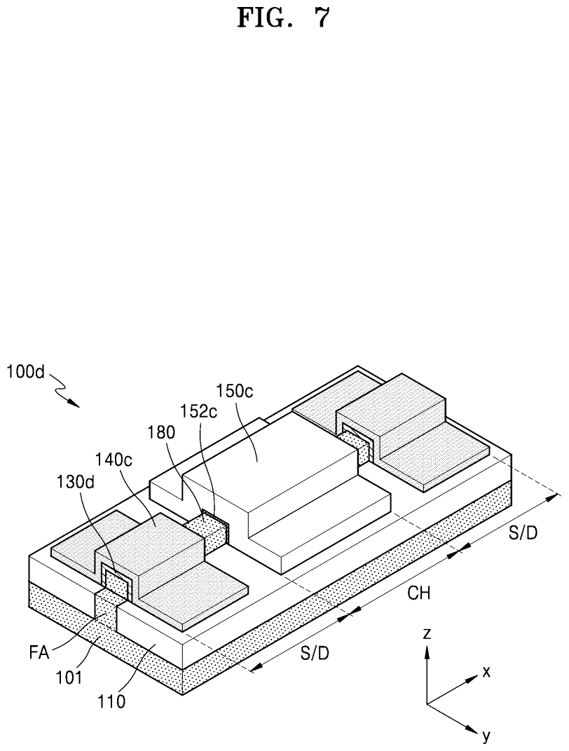

Referring to FIG. 7, the semiconductor device 100d according to an embodiment may be different from the semiconductor device 100 of FIG. 1A in that the semiconductor device 100d has a fin-FET structure. Specifically, the semiconductor device 100d according to an embodiment may include a substrate 101, a fin-upper layer 180, a junction barrier film 130d, a metal compound film 140c, a gate insulating film 152c, a gate electrode 150c, and a contact electrode. The substrate 101, the junction barrier film 130d, the metal compound film 140c, the gate electrode 150c, and the contact electrode are the same as those described in the semiconductor device 100 of FIG. 1A. However, as the fin-upper layer 180 is arranged instead of the nanowire, the structures of the junction barrier film 130d, the metal compound film 140c, the gate insulating film 152c, the gate electrode 150c, and the contact electrode may be modified. For example, the junction barrier film 130d, the metal compound film 140c, the gate insulating film 152c, the gate electrode 150c, and the contact electrode may cover three sides of the fin-upper layer 180, i.e., the top surface and both side surfaces.

The fin-upper layer 180 may correspond to an upper portion of the fin FA. Specifically, side surfaces of the lower part of the fin FA may be covered by the device isolation film 110 and a portion protruding from the top surface of the device isolation film 110 may form the fin-upper layer 180. In the semiconductor device 100d according to an embodiment, the gate electrode 150c may have a triple gate structure surrounding the outer three surfaces of the fin-upper layer 180. Accordingly, the semiconductor device 100d according to an embodiment may include a MOSFET having the triple gate structure.

In some embodiments, the junction barrier film 130d may extend from the fin-upper layer 180 portion onto the top surface of the device isolation film 110 in the Y direction. In such a structure, the extended portion of the metal compound film 140c in the Y direction may cover the extended portion of the junction barrier film 130d in the Y direction. In addition, in some embodiments, the semiconductor device 100d may have a structure in which only the junction barrier film 130d is formed on the fin-upper layer 180 and the contact electrode is formed on the junction barrier film 130d.

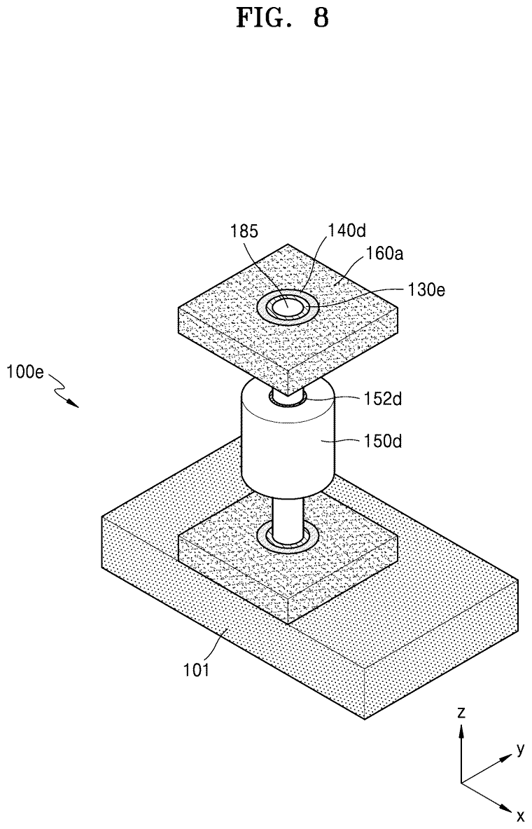

Referring to FIG. 8, a semiconductor device 100e according to an embodiment may be different from the semiconductor device 100 of FIG. 1A in that the semiconductor device 100e has a vertical FET structure. Specifically, the semiconductor device 100e according to an embodiment may include a substrate 101, a vertical semiconductor layer 185, a junction barrier film 130e, a metal compound film 140d, a gate insulating film 152d, a vertical gate electrode 150d, and a contact electrode 160a. The substrate 101, the junction barrier film 130e, the metal compound film 140d, the vertical gate electrode 150d, and the contact electrode 160a are the same as those described in the semiconductor device 100 of FIG. 1A. However, as the vertical semiconductor layer 185 is arranged instead of the nanowire, the structures of the junction barrier film 130e, the metal compound film 140d, the vertical gate electrode 150d, and the contact electrode 160a may be modified.

The vertical semiconductor layer 185 may extend in the Z direction on the substrate 101. The vertical semiconductor layer 185 may be, for example, Si or SiGe. However, the material of the vertical semiconductor layer 185 is not limited to Si or SiGe. In FIG. 8, although the vertical semiconductor layer 185 has a cylindrical shape extending in the Z direction, the vertical semiconductor layer 185 is not limited to the cylindrical shape. For example, the vertical semiconductor layer 185 may have the shape of an elliptical pillar or polygonal pillar extending in the Z direction.

For example, the vertical semiconductor layer 185 may be formed by epitaxially growing a semiconductor layer on the substrate 101 in a vertical structure. However, the vertical semiconductor layer 185 may be formed separately to form the junction barrier film 130e and the contact electrode 160a. For example, both outer portions of the vertical semiconductor layer 185 correspond to source/drain regions and a middle portion corresponds to a channel region in the Z direction, and the vertical semiconductor layer 185 may be formed in the order of a lower source/drain region, a channel region, and an upper source/drain region. As such, in some embodiments, as the lower source/drain region, the channel region, and the upper source/drain region are each formed, the vertical semiconductor layer 185 may have different sizes depending on the height in the Z direction.

A contact structure of a junction barrier film 130e, a metal compound film 140d, and a contact electrode 160a may be formed in the source/drain region and a vertical gate electrode 150d may be formed in the channel region with a gate insulating film 152d positioned in between the vertical semiconductor layer 185 and the vertical gate electrode 150d. The method of forming the junction barrier film 130e and the metal compound film 140d may be substantially the same as that described with reference to FIGS. 2A to 2C. However, because the junction barrier film 130e and the metal compound film 140d are formed on the vertical side surface of the vertical semiconductor layer 185, a process such as an etch back may be further performed. In addition, the source/drain region of the vertical semiconductor layer 185 may have a structure in which only the junction barrier film 130e is formed instead of the junction barrier film 130e and the metal compound film 140d and the contact electrode is directly formed on the junction barrier film 130e.

However, in the semiconductor device 100e according to an embodiment, the vertical gate electrode 150d is not limited to the GAA structure and may have a structure in which only a part of the side surface of the vertical semiconductor layer 185 is covered.

In some embodiments, a structure in which the junction barrier films 130, 130a to 130e are applied to the nanowires 120 and 120a, the nanosheet 170, the fin-upper layer 180, and the vertical semiconductor layer 185 has been described above. However, the structure to which the junction barrier film is applied is not limited thereto. For example, a junction barrier film can be applied to all kinds of three-dimensional source/drain structures and thus may reduce the metal-semiconductor contact resistance of the semiconductor device and induce the non-consumption of Si in the channel region.

While the inventive concept has been particularly shown and described with reference to embodiments thereof, it will be understood that various changes in form and details may be made therein without departing from the spirit and scope of the following claims.

What is claimed is:

1. A semiconductor device comprising:
a first nanowire extending in a first direction on a substrate, the first nanowire having a first end, a middle portion and a second end;
a junction barrier film surrounding the first nanowire at a first source/drain region at the first end of the first nanowire and a second source/drain region at a second end of the first nanowire in the first direction;
a gate electrode surrounding the first nanowire in a channel region in the middle portion of the first nanowire in the first direction, with a gate insulating film positioned between the gate electrode and the first nanowire; and
a contact electrode surrounding the junction barrier film.

2. The semiconductor device of claim 1, wherein the junction barrier film has a thickness of an atomic layer.

3. The semiconductor device of claim 1, further comprising a metal compound film positioned between the contact electrode and the junction barrier film.

4. The semiconductor device of claim 3, wherein the junction barrier film comprises a film remaining after a metal oxide film undergoes a metallic phase transition.

5. The semiconductor device of claim 4, wherein the metal oxide film comprises a metal oxide selected from the group consisting of MoOx, TiOx, NiOx, SnOx, TaOx, NbOx, VOx, PdOx, and WOx, and
wherein the metal compound film comprises a metal nitride or a metal sulfide.

6. The semiconductor device of claim 1, wherein the junction barrier film comprises at least one compound selected from the group consisting of a metal oxide, a metal oxynitride, a metal oxysulfide, and a silicon metal oxide.

7. The semiconductor device of claim 1, wherein the junction barrier film comprises a transition metal dichalcogenide (TMD) material and has a thickness of an atomic layer.

8. The semiconductor device of claim 7, wherein the TMD material comprises at least one compound selected from the group consisting of MoS₂, MoSe₂, MoTe₂, WS₂, WSe₂, WTe₂, NbS₂, NbSe₂, NbTe₂, TaS₂, TaSe₂, TaTe₂, PdS₂, PdSe₂, PdTe₂, VS₂, VSe₂, and VTe₂.

9. The semiconductor device of claim 1, wherein the junction barrier film comprises a compound selected from the group consisting of a metal sulfide, a metal oxide, and a metal oxysulfide.

10. The semiconductor device of claim 1, wherein the junction barrier film has a thickness of 0.7 nm to 3 nm.

11. The semiconductor device of claim 1, further comprising a second nanowire positioned above the first nanowire and extending in the first direction parallel to the first nanowire,
wherein a second junction barrier film surrounds the second nanowire at the first source/drain region and the second source/drain region at a first end and a second end of the second nanowire in the first direction, and
the gate electrode surrounds the second nanowire in a channel region in a middle portion of the second nanowire in the first direction with a second gate insulating film positioned between the gate electrode and the second nanowire.

12. A semiconductor device comprising:
a first source/drain region and a second source/drain region spaced apart from each other in a first direction on a substrate;
a junction barrier film at the first source/drain region and the second source/drain region, in a tube shape;
a channel region between the first source/drain region and the second source/drain region in the first direction;
a gate electrode at the channel region with a gate insulating film positioned under the gate electrode; and
a contact electrode over the junction barrier film.

13. The semiconductor device of claim 12, wherein the first direction is parallel to a top surface of the substrate, the first source/drain region and the second source/drain region are formed at first and second ends of a nanowire extending in the first direction, and the channel region is formed in a middle portion of the nanowire in the first direction.

14. The semiconductor device of claim 13, further comprising a metal compound film between the contact electrode and the junction barrier film, wherein the junction barrier film has a thickness of an atomic layer.

15. The semiconductor device of claim 13, wherein the junction barrier film comprises a metal sulfide or a transition metal dichalcogenide (TMD) material, and has a thickness of an atomic layer.

16. The semiconductor device of claim 12, wherein the first direction is perpendicular to a top surface of the substrate, the channel region extends in the first direction, and the first source/drain region and the second source/drain region are positioned at first and second ends of the channel region in the first direction.

17. A semiconductor device comprising:
a first source/drain region and a second source/drain region formed at first and second ends of a nanowire extending in a first direction on a substrate;
a channel region formed in a middle portion of the nanowire in the first direction;
a junction barrier film surrounding the nanowire in a tube shape at the first source/drain region and the second source/drain region;
a gate electrode surrounding the nanowire at the channel region with a gate insulating film positioned between the nanowire and the gate electrode; and
a contact electrode surrounding the junction barrier film, wherein the junction barrier film has a thickness of an atomic layer.

18. The semiconductor device of claim 17, further comprising a metal compound film positioned between the contact electrode and the junction barrier film and formed by a metallic phase transition of a metal oxide film, wherein the junction barrier film comprises a film remaining after the metal oxide film undergoes the metallic phase transition.

19. The semiconductor device of claim 18, wherein
the metal oxide film comprises a compound selected from the group consisting of MoOx, TiOx, NiOx, SnOx, TaOx, NbOx, VOx, PdOx, and WOx, and
the metal compound film comprises a metal nitride or a metal sulfide.

20. The semiconductor device of claim 17, wherein the junction barrier film comprises a metal sulfide or a transition metal dichalcogenide (TMD) material.
